(19) United States
(12) Patent Application Publication
(10) Pub. No.: US 2026/0280234 A1
(43) Pub. Date: Sep. 17, 2026

(54) LASER EMITTER ASSEMBLY

(71) Applicant: TRUMPF Laser SE, Schramberg (DE)

(72) Inventors: Stephan Strohmaier, Berlin (DE); Thomas Rataj, Berlin (DE); Christoph Tillkorn, Villingendorf (DE)

(21) Appl. No.: 19/678,208

(22) Filed: May 15, 2026

Related U.S. Application Data
(63) Continuation of application No. PCT/EP2024/083679, filed on Nov. 27, 2024.

(30) Foreign Application Priority Data
Dec. 1, 2023 (DE) 10 2023 133 707.6

(51) Int. Cl. H01S 5/40

(52) U.S. Cl. CPC H01S 5/4012; H01S 5/4031

(57) ABSTRACT

A laser emitter assembly for providing an output laser beam at an output of the laser emitter assembly includes a base, a plurality of laser emitter devices, and a plurality of deflecting mirrors secured to the base. Each respective laser emitter device is configured to generate a respective laser beam. Each respective deflecting mirror is paired with a respective laser emitter device. Each respective deflecting mirror is configured to deflect the respective laser beam of the respective laser emitter device paired with the respective deflecting mirror. Each respective deflecting mirror has a straight edge that runs diagonally with respect to the base. The output laser beam is formed from the laser beams of the plurality of laser emitter devices.

### CROSS REFERENCE TO RELATED APPLICATIONS

This application is a continuation of International Application No. PCT/EP2024/083679 (WO 2025/114313 A1), filed on Nov. 27, 2024, and claims benefit to German Patent Application No. DE 10 2023 133 707.6, filed on Dec. 1, 2023. The aforementioned applications are hereby incorporated by reference herein.

### FIELD

Embodiments of the present invention relate to a laser emitter assembly.

### BACKGROUND

A laser emitter assembly can provide an output laser beam, for example for an optical pumping of a laser-active medium of a solid-state laser. The solid-state laser can be designed, for example, as a disk laser or a fiber laser. Consequently, the output laser beam provided by the laser emitter assembly can be suitable for optical pumping, for example of solid-state lasers.

In addition to optical pumping, other applications for the output laser beam of the laser emitter assembly can exist-if the output laser beam is provided with a certain power, for example in the processing of workpieces or in medical technology. In such applications, the output laser beam can not only function as an optical pump source, but can at least be designed as an unamplified processing/treatment laser beam.

### SUMMARY

Embodiments of the present invention provide a laser emitter assembly for providing an output laser beam at an output of the laser emitter assembly. The laser emitter assembly includes a base, a plurality of laser emitter devices, and a plurality of deflecting mirrors secured to the base. Each respective laser emitter device is configured to generate a respective laser beam. Each respective deflecting mirror is paired with a respective laser emitter device. Each respective deflecting mirror is configured to deflect the respective laser beam of the respective laser emitter device paired with the respective deflecting mirror. Each respective deflecting mirror has a straight edge that runs diagonally with respect to the base. The output laser beam is formed from the laser beams of the plurality of laser emitter devices.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 shows a schematic top view of a laser emitter assembly according to some embodiments;

FIG. 2 shows a schematic diagonal view of the laser emitter assembly of FIG. 1 according to some embodiments;

FIG. 3 shows another schematic diagonal view of the laser emitter assembly from FIG. 1 according to some embodiments;

FIG. 4 shows a schematic diagonal view of a laser emitter device of the laser emitter assembly of FIG. 1 without a fast-axis collimator lens according to some embodiments;

FIG. 5 shows a schematic side view of the laser emitter device of FIG. 4 with a fast-axis collimator lens according to some embodiments;

FIG. 6 shows a schematic representation of a deflecting mirror of the laser emitter assembly of FIG. 1 according to some embodiments;

FIG. 7 shows a schematic diagonal view of the deflecting mirror from FIG. 6 according to some embodiments;

FIG. 8 shows a schematic representation of an optical device of the laser emitter assembly of FIG. 1 according to some embodiments;

FIG. 9 shows a schematic representation of a cross-section of an output laser beam provided by the laser emitter assembly of FIG. 1 according to some embodiments;

FIG. 10 shows a schematic representation of a further exemplary embodiment of a laser emitter assembly according to some embodiments;

FIG. 11 shows a schematic top view of another exemplary embodiment of a laser emitter assembly according to some embodiments;

FIG. 12 shows a schematic top view of another exemplary embodiment of a laser emitter assembly according to some embodiments;

FIG. 13 shows a schematic diagonal view of the laser emitter assembly from FIG. 12 according to some embodiments;

FIG. 14 shows another schematic diagonal view of the laser emitter assembly from FIG. 12 according to some embodiments;

FIG. 15 shows a schematic representation of a section of a cross-section of an output laser beam provided by the laser emitter assembly of FIG. 12 according to some embodiments;

FIG. 16 shows a schematic top view of another exemplary embodiment of a laser emitter assembly according to some embodiments;

FIG. 17 shows a schematic diagonal view of the laser emitter assembly of FIG. 16 according to some embodiments;

FIG. 18 shows another schematic diagonal view of the laser emitter assembly from FIG. 16 according to some embodiments;

FIG. 19 shows a schematic diagonal view of a region XIX according to FIG. 17 according to some embodiments;

FIG. 20 shows another schematic diagonal view of the region XIX according to FIG. 17 according to some embodiments; and

FIG. 21 shows a schematic representation of a coupling element of the laser emitter assembly of FIG. 16 according to some embodiments.

### DETAILED DESCRIPTION

Embodiments of the present invention provide a laser emitter assembly which has improved properties, in particular is cost-effective to manufacture and/or is suitable for providing a high-power output laser beam.

A laser emitter assembly according to embodiments of the invention is designed to provide an output laser beam at an output of the laser emitter assembly. The laser emitter assembly has a base, a plurality of, for example 8 to 30, in particular 10 to 25, laser emitter devices and a plurality of, for example 8 to 30, in particular 10 to 25, deflecting mirrors. The plurality of deflecting mirrors are secured to the base. Each laser emitter device is designed to generate a laser beam. Each deflecting mirror is paired with a laser emitter device. Each deflecting mirror is designed to deflect the laser beam of the laser emitter device paired with the deflecting mirror. Each deflecting mirror has a straight edge that runs diagonally with respect to the base. The output laser beam is formed from the laser beams of the laser emitter devices.

Advantageously, due to the straight edge running diagonally with respect to the base, a particularly clear and simple setup of the laser emitter assembly can be achieved. Furthermore, due to running diagonally to the straight edge, the number of components required for providing the output laser beam at the output can be reduced, so that very few components are needed to realize the laser emitter assembly, making the laser emitter assembly particularly cost-effective. Considering that each component over which a laser beam is passed can reduce the power of the laser beam, the power losses of the laser emitter assembly can be advantageously kept small due to the small number of components required, which is why the laser emitter assembly is particularly suitable for providing a high-power output laser beam.

A straight edge can be understood as one that extends along a straight line. The straight edge can be formed without curvature.

Any straight edge that has a diagonal run with respect to the base can be described as a straight edge that runs diagonally to the base, in particular as being diagonally aligned.

A straight edge that runs diagonally to the base, and in particular is diagonally aligned, can be understood to mean that the straight edge does not run parallel to the base.

The mirror can be designed as a metal mirror or a Bragg mirror.

The straight edge of each deflecting mirror can limit a mirror surface of the deflecting mirror. Each mirror surface of the deflecting mirrors can be designed to deflect the laser beam, in particular by reflecting the laser beam. In other words, the mirror surface can be designed to reflect the laser beam. Each mirror surface can be aligned to be perpendicular to the base. The mirror surfaces can, at least partially, also form an angle with the base that deviates from 90°.

The straight edge can be designed as a corner of the deflecting mirror.

The plurality of deflecting mirrors can be the same as the plurality of laser emitter devices. Each laser emitter device can be paired with a single deflecting mirror.

Each laser beam can propagate along a direction of propagation. The deflection of the laser beam by means of a deflecting mirror can change the direction of propagation of the laser beam.

The base can be formed to be cuboid. The height of the base can be less than the width and/or length of the base.

The base can be designed to be secured to an object, for example, an optical table. The base can have a number of elements, for example in the form of through-holes and/or threads, for securing the base to the object.

The deflecting mirrors can be connected to the base in a form-fitting manner and/or in a material-fitting manner. For example, the deflecting mirrors can be secured to the base by means of an adhesive bond, a soldered connection, or a welded connection. The adhesive bond can be created by means of a UV adhesive. The UV adhesive can be an adhesive that can be hardened by irradiation with ultraviolet light.

Each laser beam can have a fast-axis direction and a slow-axis direction.

Each laser emitter device can have at least one emitter for generating the laser beam and a fast-axis collimator lens for collimating the laser beam in the fast-axis direction.

The fast-axis direction and the slow-axis direction can be aligned to be orthogonal to each other. The laser beam emerging from the emitter can define the fast-axis direction and the slow-axis direction. The laser beam emerging from the emitter can propagate in the fast-axis direction with a larger divergence angle than in the slow-axis direction. In other words, when the laser beam exits the emitter, the laser beam can propagate along the direction of propagation thereof, wherein a diameter of the laser beam increases more in the fast-axis direction up to a fast-axis collimator lens of the laser emitter device than a diameter of the laser beam in the slow-axis direction.

Each laser beam can have a diffraction index M² in a range of 1 to 2 in the fast-axis direction, and a diffraction index M² in a range of 14 to 50 in the slow-axis direction. The diffraction indices M² of the laser beams in the fast-axis direction can be the same, in particular in the magnitudes thereof. Additionally or alternatively, the diffraction coefficients M² of the laser beams must be the same in the slow-axis direction, in particular in the magnitudes thereof.

The term emitter can refer to a laser diode bar. Each emitter can contain a semiconductor laser material. Each laser emitter device can have a single emitter. Each laser emitter device can have a “chip on submount” design.

Each emitter can extend along a longitudinal axis. Each longitudinal axis of the emitters can be aligned to be parallel to the base. The longitudinal axes of the emitters can be aligned to be parallel to each other.

The emitter can be arranged, in particular secured, to a mounting plate of the laser emitter device. The mounting plate can be arranged on the emitter forming a planar interface that is orthogonal to the fast-axis direction. The flat interface can be aligned to be parallel to the base.

The fast-axis collimator lens can be a cylindrical lens, in particular an aspherical cylindrical lens. The fast-axis collimator lens can be made of quartz glass. The fast-axis collimator lens can have an anti-reflective coating for a wavelength of the laser beam of the laser emitter device. The anti-reflective coating can be suitable for reducing the reflectance of the laser beam at interfaces of the fast-axis collimator lens. The fast-axis collimator lens can be secured to the mounting plate, in particular by means of an adhesive bond. The adhesive bond can be created, for example, by means of a UV adhesive.

The laser emitter devices can be identical in construction. In particular, the laser emitter devices can be designed to be identical.

The laser emitter assembly can include an optical device located between the output and the plurality of laser emitter devices. The laser beams can pass through the optical device for the purpose of changing the directions of propagation of the laser beams. The optical device can be secured to the base.

The optical device can be designed to align the directions of propagation of the laser beams parallel to the base and/or to the longitudinal axes of the emitters.

Any laser beam can strike the optical device at an angle of incidence other than 0° for the purpose of changing the direction of propagation. The optical device can be wedge-shaped and/or designed as an optical wedge. The optical device can be designed to change the directions of propagation of the laser beams by refraction of the laser beams, for example in the direction of the base. The optical device can be designed to change the directions of propagation of the laser beams, in particular only in the fast-axis direction.

The output laser beam can be a laser beam group formed from the laser beams.

Preferably, the output laser beam can consist of the laser beams. The initial laser beam can propagate in a direction. The direction of propagation of the output laser beam can be aligned to be parallel to the base.

The output laser beam can be formed to be coupled into a waveguide for guiding the output laser beam. The waveguide can be, for example, an optical fiber or a fiber optic cable. The output laser beam can be formed to be coupled into the waveguide if an end face of the waveguide is located at the output. It is also conceivable that the laser emitter assembly can have the waveguide and the output is formed by the end face of the waveguide. Alternatively, the output can be formed through an opening in a housing of the laser emitter assembly.

The output laser beam can be formed by directing the laser beams towards the output, in particular by means of deflecting mirrors.

The output laser beam can exit the output with a predetermined beam diameter and divergence, pass through the output and/or be guided through the output. In other words, the output can be provided for the exit of the output laser beam from the laser emitter assembly.

At the output, the output laser beam can have a beam diameter in the range of, for example, 100 μm (micrometers) to 1500 μm, in particular 200 μm to 500 μm. At the output, the output laser beam can have a divergence angle in the range of, for example, 5° to 40°, in particular 10° to 25°.

The laser emitter assembly can include a focusing device, for example in the form of a focusing lens, for focusing the output laser beam onto the output. The focusing lens can be made of quartz glass. The focusing lens can have an anti-reflective coating for a wavelength of the laser beams from the laser emitter devices. The anti-reflective coating can be suitable for reducing the reflection of laser beams at interfaces of the focusing lens. The focusing lens can be radially symmetrical. However, it can also have two cylindrical lenses perpendicular to each other and possibly cemented or glued together, and in particular be formed thereby.

The output can be located in a focal plane of the focusing device. The focal plane can be located in the directions of propagation of the laser beams after the focusing device. The output can be limited by a maximum focus diameter of the focusing device in the focal plane. The maximum focus diameter can depend on the apertures of the emitters.

The laser emitter assembly can have a waveguide receptacle for a waveguide. The waveguide receptacle can be located at an opening in the housing of the laser emitter assembly. The housing can have an interior in which the laser emitter devices are arranged. A waveguide can be received from the waveguide receptacle. The waveguide can be received by the waveguide receptacle in such a way that an end face of the waveguide is located at the output. The output laser beam can be formed from the laser beams and focused onto the end face of the waveguide by means of the focusing device. By focusing the output laser beam onto the end face of the waveguide, the output laser beam can be coupled into the waveguide. The end face can have an anti-reflective coating that is particularly low in reflectivity for a specific wavelength of the laser beams.

Alternatively, the output can be an opening in a housing of the laser emitter assembly. The housing can have an interior in which the laser emitter devices are arranged. The output laser beam can be formed from the laser beams and focused onto the opening by means of the focusing device. The output laser beam can be guided through the opening by means of the focusing device. However, the output laser beam can also pass through the opening and only then enter the focusing device if the focusing device is located outside the housing of the laser emitter assembly. A sealing element that transmits the wavelength of the laser beams, for example in the form of a transparent protective glass, can be arranged in or adjacent to the opening, which largely prevents unwanted foreign particles from entering the interior of the housing.

According to embodiments of the invention, a laser beam that does not propagate parallel to the base can be guided past the edge with the diagonal run of a deflecting mirror with no or only slight power loss for the purpose of forming the output laser beam. This allows the diagonal run of the straight edge to enable a particularly dense and/or compact arrangement of the laser beams next to each other for the purpose of creating the image of the output laser beam, which is why the laser emitter assembly can provide an output laser beam that is formed from a higher number of laser beams. Therefore, the laser emitter assembly can provide an output laser beam with particularly high power.

In a further development of the laser emitter assembly, the straight edge with the diagonal run of each deflecting mirror defines a side surface of the deflecting mirror that faces away from the base. The straight edge of each deflecting mirror can form a boundary between the mirror surface and the side surface. The side surface of each deflecting mirror can be designed as a flat surface.

Each deflecting mirror can have an additional side surface. The other side surface of each deflecting mirror can be arranged to be opposite to the side surface. The other side surface of each deflecting mirror can face the base. The other side surface of each deflecting mirror can be designed as a flat surface. The other side surface of each deflecting mirror can be aligned to be parallel to the base. The other side surface of each deflecting mirror can contact the base.

In each deflecting mirror, the side surface and the other side surface can be aligned in opposite directions to each other.

In a further development of the laser emitter assembly, the base has a flat surface section. The deflecting mirrors are arranged on the flat surface section. The straight edge with the diagonal run of each deflecting mirror exhibits the diagonal run in relation to the flat surface section. Advantageously, producing the flat surface section can be particularly simple and cost-effective.

The flat surface section can be a contiguous surface section. The flat surface section can be an uninterrupted surface section. The flat surface section can be arranged in a single plane of the base. Alternatively, the flat surface section can define a single plane of the base. The flat surface section can form a surface of the base. The surface formed by the flat area section can be arranged in one, in particular single, plane. The base can have a single flat surface section for arranging the deflecting mirrors. The deflecting mirrors can be arranged on a single flat surface section. The flat surface section can have a first region containing a first material and a second region containing a second material, wherein the two materials can be different from each other. The first material could be, for example, a metal material, in particular copper (Cu). The second material can, for example, be a ceramic material. In this case, the laser emitter devices can be located on the region with the first material and the deflecting mirrors on the region with the second material.

The plurality of laser emitter devices can be arranged on the flat surface section. The laser emitter devices can be arranged at a distance from each other on the flat surface section.

The laser emitter devices can be arranged on the flat surface section in such a way that the slow-axis directions of the laser beams extend parallel to the flat surface section, and in particular are aligned.

The laser emitter devices can be arranged on the flat surface section in such a way that the longitudinal axes of the emitters are aligned to be parallel to the flat surface section.

Each laser emitter device can have a laser emitter output from which the laser beam exits. Each laser emitter output can be spaced at a distance from the flat surface section. The distances of the laser emitter outputs from the flat surface section can be the same.

In a further development of the laser emitter assembly, each laser beam propagates along a direction of propagation. Each deflecting mirror is designed to deflect the direction of propagation of the laser beam of the laser emitter device paired with the deflecting mirror by 80° to 100°, in particular 85° to 95° or 88° to 92°, preferably 90°. Advantageously, a particularly compact construction of the laser emitter assembly can be achieved with deflecting mirrors designed in this manner. The directions of propagation of the laser beams can be aligned to be parallel to each other before deflection by means of the deflecting mirrors and/or after deflection by means of the deflecting mirrors. The angle of incidence of each laser beam on the deflecting mirror can be, for example, 40° to 50°, in particular 42.5° to 47.5° or 44° to 46°, preferably 45°.

In a further development of the laser emitter assembly, the laser emitter devices are secured to the base. Each laser emitter device is designed to emit the laser beam in a direction. Each emission direction and the base, in particular the flat surface section, define a radiation angle α therebetween. The straight edge of each deflecting mirror, which runs diagonally with respect to the base, in particular the diagonal run of the straight edge of each deflecting mirror and the base, in particular the flat surface section, define an angle α′ therebetween which depends on the radiation angle α, in particular that of the laser emitter device paired with the deflecting mirror. Advantageously, each deflecting mirror can be formed in such a way that, due to the dependence of the angle α′ on the radiation angle α, a mirror surface of the deflecting mirror which is not used for deflecting the laser beam is particularly small. Advantageously, it can be achieved through the dependence of the angle α′ on the radiation angle α that laser beams are guided past the deflecting mirrors with the lowest possible power loss.

For example, the dependence of the angle α′ on the radiation angle α is such that a laser beam deflected by means of a deflecting mirror is guided past a further deflecting mirror following in the direction of propagation of the deflected laser beam, so that the further subsequent deflecting mirror blocks no more than 5%, in particular 2% or 0.5%, of the power of the deflected laser beam.

The straight edge can be aligned at an angle α′ with respect to the base, in particular the flat surface section.

For radiation angles of less than 5°, the diagonal run with respect to the base, in particular the flat surface section, can fulfill the condition

$${α}^{′} \approx \frac{α}{\sqrt{2}} .$$

in other words, if α<5°, then the diagonal run with respect to the base, in particular the flat surface section, can fulfill the condition

$${α}^{′} \approx \frac{α}{\sqrt{2}} .$$

The radiation angles α can each have the same magnitude. Each radiation angle α can be unequal to 0°. Each radiation angle α can be greater than 0°. Each radiation angle between the direction of emission and the base, in particular to the flat surface section, can be 0.5° to 20°, in particular 0.5° to 10°, 1° to 5° or 2° to 4°.

The emission directions can be aligned to be parallel to each other. In particular, any laser emitter device can be designed to emit a laser beam in the emission direction in such a way that the laser beam propagates along the direction of propagation thereof, which is the same as the emission direction. In other words, the emission directions and the directions of propagation of the laser beams can be the same.

Due to the emission of the laser beams in the emission direction, the distance between the laser beam and the flat surface section can depend on the propagation path traveled by the laser beam in each case. In other words, the distance can change depending on the propagation path traveled by the laser beam. In particular, the distance can increase depending on the propagation path traveled by the laser beam. Preferably, the distance can increase proportionally with the propagation path traveled by the laser beam. The propagation path traveled by the laser beam can be the propagation path traveled from the laser emitter device that emits the laser beam. The output laser beam can be formed from the laser beams, depending on the propagation path traveled and/or the distance between the laser beam and the base.

Distance can be understood as height, in particular a height between a laser beam and the flat surface section. The distance can be determined perpendicularly, in particular parallel to a perpendicular on the flat surface section.

The optical device can be arranged on the flat surface section. The optical device can be designed to align the directions of propagation of the laser beams to be parallel to the flat surface section. The optical device can be designed to change the directions of propagation of the laser beams by refraction of the laser beams, for example in the direction of the flat surface section of the base.

In the direction of propagation after the optical device, the distance between the laser beam and the flat surface section from the optical device onwards can be constant. In other words, once a laser beam has passed through the optical device, the distance between the laser beam and the flat surface section can be constant from the optical device onwards.

The base can be designed as a cooled plate for cooling the laser emitter devices. The base can be designed to allow flow of a cooling medium, for example cooling water, for the purpose of cooling the laser emitter devices. However, it is also possible to cool the base directly or indirectly via a separate cooling plate. In the case of indirect cooling, a heat transfer layer can be arranged between the base and the cooling plate, which has a material with a comparatively high thermal conductivity coefficient, for example a carbon material, in particular graphite. The cooling plate can be designed to allow flow through or over the laser emitter devices for the purpose of cooling. The heat transfer layer can have a thickness of 50 μm to 1000 μm, in particular 100 μm to 500 μm, preferably 150 μm to 250 μm, and particularly preferably 200 μm.

Each laser emitter device can be secured to the base by means of the mounting plates. In particular, the mounting plate can be used to secure any laser emitter device to the base.

The laser emitter devices can be connected to the base in a form-fitting manner and/or in a material-fitting manner. For example, the laser emitter devices can be secured to the base by means of an adhesive bond, a soldered connection, or a welded connection. The adhesive bond can be created by means of a UV adhesive. The UV adhesive can be an adhesive that can be hardened by irradiation with ultraviolet light. Additionally or alternatively, the adhesive bond can be made by means of an adhesive that has a thermal conductivity of over 0.5 watts/(meter*kelvin).

The laser emitter devices can be thermally connected to the base in such a way that the connection between each laser emitter device and the base has a thermal conductivity of at least 0.5 watts/(meter*kelvin). In particular, the thermal conductivity of the connection between each laser emitter device and the base can range from 0.5 watts/(meter*kelvin) to 150 watts/(meter*kelvin).

In a further development of the laser emitter assembly, the angle α′ fulfills the condition

$${α}^{′} = a tan ( \frac{tan α}{\sqrt{2}} ) .$$

Each laser beam can strike the deflecting mirror at an angle of incidence of 45°.

In a further development of the laser emitter assembly, at least one deflecting mirror designed in this manner is provided to deflect the laser beam of the laser emitter device paired with the deflecting mirror in such a way that the deflected laser beam is guided past the straight edge with the diagonal run of another deflecting mirror. This advantageously allows for a particularly compact design of the laser emitter assembly.

At least one laser beam can be guided past each deflecting mirror, except for the deflecting mirror furthest from the output, along the straight edge with the diagonal run towards the base.

The additional deflecting mirror can be positioned between the laser beam deflected by the deflecting mirror and the base. Each deflecting mirror, except for the one furthest from the output, can be positioned between a laser beam and the base.

The output laser beam can be formed by arranging the laser beams with respect to each other, in particular by means of deflecting mirrors. The forming of the output laser beam can involve arranging the laser beams one above the other in the fast-axis direction. In a cross-section of the output laser beam, the laser beams can be arranged one above the other in the fast-axis direction, for example at equal distances from each other. In the cross-section of the output laser beam, the laser beams can overlap, at least in some regions.

The laser beams can be arranged in the cross-section of the output laser beam to form a laser beam array. The laser beam array can be aligned to be perpendicular to the base, in particular the flat surface section. The laser beam array can be formed, for example, by guiding each laser beam, except for the laser beam for which the paired deflecting mirror is closest to the output, past the diagonally-running straight edges of the subsequent deflecting mirrors after deflection by means of the deflecting mirror.

In a further development of the laser emitter assembly, the plurality of deflecting mirrors are secured to the base to forming at least one array of deflecting mirrors. Advantageously, this allows for a particularly simple arrangement of the laser beams on top of each other in the fast-axis direction. A direction of the deflecting mirror array can run parallel to the base, in particular parallel to the flat surface section of the base. For example, the plurality of deflecting mirrors can be secured to the base, forming a single array of deflecting mirrors.

In a further development of the laser emitter assembly, the plurality of laser emitter devices are secured to the base, forming at least one array of laser emitters. This makes it particularly easy to generate the initial laser beam. The deflecting mirrors can be of identical construction.

In a further development of the laser emitter assembly, the deflecting mirror array and the laser emitter array are arranged to be parallel to each other. This advantageously allows for a particularly clear and simple design of the laser emitter assembly.

In a further development of the laser emitter assembly, the plurality of deflecting mirrors are secured to the base, forming a first deflecting mirror array and a second deflecting mirror array.

The deflecting mirrors can have a first number of deflecting mirrors secured to the base to form the first array of deflecting mirrors, and a second number of deflecting mirrors secured to the base to form the second array of deflecting mirrors.

The laser emitter devices can be secured to the base, forming a first laser emitter array and a second laser emitter array. The first array of deflecting mirrors can be paired with the first array of laser emitters. The second array of deflecting mirrors can be paired with the second array of laser emitters.

The first array of laser emitters and the second array of laser emitters can be aligned to be parallel to each other. The first array of laser emitters and the second array of laser emitters can be arranged to be offset from each other.

The output laser beam can be formed such that the laser beams of the first laser emitter array and the laser beams of the second laser emitter array are arranged alternately at the output. The output laser beam can also be formed by laser beams from the first and second laser emitter arrays superimposing accordingly.

In a further development of the laser emitter assembly, the first array of deflecting mirrors and the second array of deflecting mirrors are aligned to be parallel to each other. The first array of deflecting mirrors and the first array of laser emitters can be aligned to be parallel to each other. The second array of deflecting mirrors and the second array of laser emitters can be aligned to be parallel to each other.

In a further development of the laser emitter assembly, the first array of deflecting mirrors and the second array of deflecting mirrors are arranged to be offset from each other. This advantageously allows for a particularly compact design of the laser emitter assembly. By staggering the arrangement of the first and second arrays of deflecting mirrors, a laser beam from a laser emitter device of the second laser emitter array can be guided between two adjacent deflecting mirrors of the first array of deflecting mirrors.

In a further development of the laser emitter assembly, the output laser beam is formed by polarization coupling and/or wavelength coupling of the laser beams deflected by means of the first array of deflecting mirrors with the laser beams deflected by means of the second array of deflecting mirrors.

The output laser beam can be formed in such a way that at least between two adjacent laser beams, which are deflected by means of the first array of deflecting mirrors, a laser beam, which is deflected by means of the second array of deflecting mirrors, is arranged.

For example, the laser emitter assembly has a wavelength coupling device for forming the output laser beam by wavelength coupling of the laser beams deflected by means of the first array of deflecting mirrors with the laser beams deflected by means of the second array of deflecting mirrors. The output laser beam can be formed by wavelength coupling of the laser beams deflected by means of the first array of deflecting mirrors with the laser beams deflected by means of the second array of deflecting mirrors by means of the wave coupling device.

For wavelength coupling, the laser beams deflected by means of the first array of deflecting mirrors can have a different wavelength than the laser beams deflected by means of the second array of deflecting mirrors. For example, the amount of the difference between the wavelengths of the laser beams deflected by means of the first array of deflecting mirrors and the wavelengths of the laser beams deflected by means of the second array of deflecting mirrors can be 3 nm (nanometers) to 25 nm, in particular 5 nm to 15 nm. The wavelength coupling device can, for example, include a mirror that is transmitting for the wavelengths of the laser beams deflected by means of the second array of deflecting mirrors and reflecting for the wavelengths of the laser beams deflected by means of the first array of deflecting mirrors. The output laser beam can be formed by means of spatially superimposing the laser beams deflected by means of the first array of deflecting mirrors with the laser beams deflected by means of the first array of deflecting mirrors.

For example, the laser emitter assembly includes a polarization coupling device for the forming of the output laser beam by polarization coupling of the laser beams deflected by means of the first array of deflecting mirrors with the laser beams deflected by means of the second array of deflecting mirrors. The output laser beam can be formed by polarization coupling of the laser beams deflected by means of the first array of deflecting mirrors with the laser beams deflected by means of the second array of deflecting mirrors, by means of the polarization coupling device.

The polarization coupling device can include a polarizer and a delay plate in the form of a λ/2 plate. The laser beams deflected by means of the first array of deflecting mirrors and the laser beams deflected by means of the second array of deflecting mirrors can be linearly polarized. The polarization of the laser beams deflected by means of the first array of deflecting mirrors and the polarization of the laser beams deflected by means of the second array of deflecting mirrors can be aligned in the same direction before passing through the polarization coupling device. The λ/2 plate can be arranged such that the laser beams, which are deflected by means of the first array of deflecting mirrors, pass through the λ/2 plate. The λ/2 plate can be designed to rotate the polarization of the laser beams, which are deflected by means of the first array of deflecting mirrors, by 90°. The polarization of the laser beams deflected by means of the first array of deflecting mirrors can be aligned to be orthogonal to the polarization of the laser beams deflected by means of the second array of deflecting mirrors after passing through the λ/2 plate. The polarizer can be designed to transmit the polarization of the laser beams deflected by means of the second array of deflecting mirrors and to reflect the polarization of the laser beams deflected by means of the first array of deflecting mirrors. The output laser beam can be formed by spatially superimposing the laser beams deflected by means of the first array of deflecting mirrors with the laser beams deflected by means of the second array of deflecting mirrors, by means of the polarizer.

The first array of deflecting mirrors and the second array of deflecting mirrors can independently generate a particularly dense arrangement of the laser beams in the fast-axis direction. Through polarization coupling and/or wavelength coupling, the laser beams deflected by means of the first array of deflecting mirrors and the laser beams deflected by means of the second array of deflecting mirrors can be superimposed in such a way that the output laser beam has a particularly smooth intensity profile in the cross-section thereof in the fast-axis direction.

In a further development of the laser emitter assembly, each laser beam travels a propagation path from the laser emitter device generating the laser beam to the output of the laser emitter assembly. The output laser beam is formed from the laser beams of the laser emitter devices depending on the propagation paths from the laser emitter devices to the output. This makes it particularly easy to generate the initial laser beam.

The laser beams can have different propagation paths from each other.

The position of a laser beam in the cross-section of the output laser beam, in particular at the output, can depend on the length of the propagation path thereof. In other words, the length of the propagation path of a laser beam can determine the position thereof in the cross-section of the output laser beam, in particular at the output. In other words, the arrangement of the laser beams, in particular with respect to each other, in the cross-section of the output laser beam, particularly at the output, can depend on the lengths of the propagation paths.

In a further development of the laser emitter assembly, the laser emitter devices can be arranged on the flat surface section by forming a first laser emitter array and a second laser emitter array. Each radiation angle between the emission direction of a laser emitter device of the first laser emitter array and the flat surface section can be smaller in magnitude than the magnitude of the radiation angle between the emission direction of a laser emitter device of the second laser emitter array and the flat surface section. Each deflecting mirror can be paired with a laser emitter device. The deflecting mirrors paired with the laser emitter devices of the second laser emitter array can each be aligned to be orthogonal to the base, in particular the flat surface section. The deflecting mirrors paired with the laser emitter devices of the first laser emitter array can each be aligned with a tilt angle to the base, in particular the flat surface section. The deflecting mirrors, which are paired with the laser emitter devices of the first laser emitter array, can each be aligned with the tilt angle to that of the base, in particular the flat surface section, such that the laser beams of the laser emitter devices of the first laser emitter array and the laser beams of the laser emitter devices of the second laser emitter array are aligned to be parallel to each other after deflection by means of the deflecting mirrors.

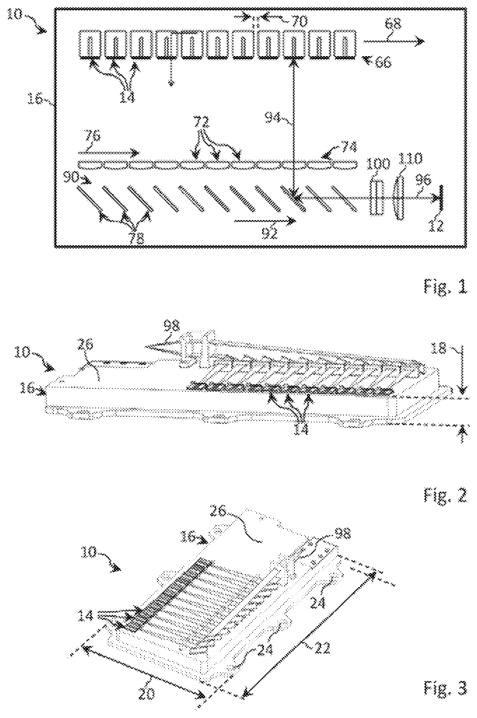

FIGS. 1 to 3 show a laser emitter assembly 10. The laser emitter assembly 10 is designed to provide an output laser beam at an output 12 of the laser emitter assembly 10.

The laser emitter assembly 10 has a plurality of identical laser emitter devices 14 and a base 16.

The base 16 is cuboid in shape. A height 18 of the base is smaller than a width 20 and a length 22 of the base 16.

The base 16 is designed to be secured to an object, for example an optical table and/or a housing part of an enclosing housing for the laser emitter assembly 10. The base 16 has a number of through-holes 24 for securing the base 16 to the object. For example, the base 16 can be secured to the object by means of a screw connection, wherein the screws of the screw connection are guided through the through-holes 24. In the illustrated exemplary embodiment, the base 16 has six through-holes 24. However, a base with a lower or higher number of through-holes 24 is also conceivable.

The base 16 has a flat surface section 26. The flat area section 26 is a continuous and uninterrupted area section. The flat surface section 26 forms a single plane of the base 16. The flat surface section 26 is a surface of the base 16.

The laser emitter devices 14 are arranged on the flat surface section 26 and secured to the base 16. In the illustrated exemplary embodiment, the laser emitter assembly 10 has a total of 11 laser emitter devices 14. However, a laser emitter assembly with a lower or higher number of laser emitter devices is also conceivable. In exemplary embodiments not specifically shown, for example, only eight laser emitter devices 14 or up to 32 laser emitter devices 14 are present.

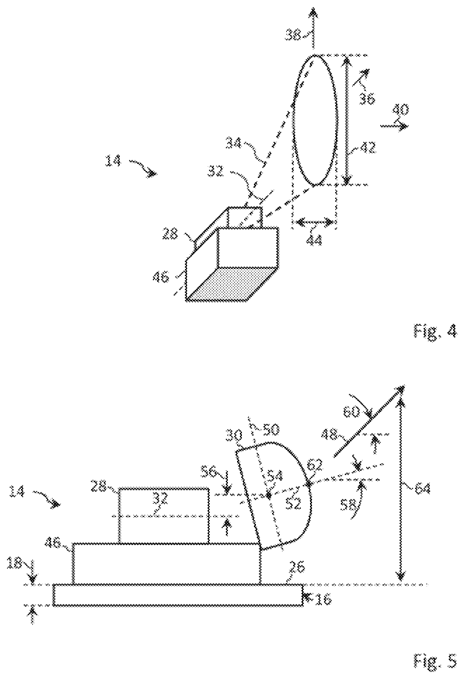

Each laser emitter device 14 has an emitter 28 made of a semiconductor laser material and a fast-axis collimator lens 30. In FIG. 4 a single laser emitter device 14 of the laser emitter assembly 10 is shown without the fast-axis collimator lens 30.

FIG. 4 shows that the laser emitter device 14 has a single emitter 28. The emitter 28 extends along a longitudinal axis 32. The emitter 28 is designed to generate a laser beam 34. The laser emitter device 14 is thus designed to generate the laser beam 34. The longitudinal axis 32 of the emitter 28 is aligned to be parallel to the flat surface section 26.

In the illustrated exemplary embodiment of FIG. 4 the emitter 28 emits the laser beam 34. The laser beam 34 propagates along its direction of propagation 36. The direction of propagation 36 and the longitudinal axis 32 of the emitter 28 are aligned to be parallel to each other. In particular, the direction of propagation 36 and the longitudinal axis 32 of the emitter 28 can have the same orientation.

The laser beam 34 emerging from the emitter 28 defines a fast-axis direction 38 and a slow-axis direction 40, which are orthogonal to each other. When the laser beam 34 exits the emitter 28, the laser beam 34 propagates along the direction of propagation 36 thereof, wherein a diameter 42 of the laser beam 34 increases more in the fast-axis direction 38 than a diameter 44 of the laser beam 34 in the slow-axis direction 40. Consequently, the laser beam 34 has an elliptical cross-section after exiting the emitter 28.

The emitter 28 is arranged on and held by a mounting plate 46 of the laser emitter device 14. The holding plate 46 contacts the emitter 28 in a planar interface that is orthogonal to the fast-axis direction 38. The flat boundary surface is aligned to be parallel to the flat surface section 26.

FIG. 5 shows the laser emitter device 14 of FIG. 4 with the fast-axis collimator lens 30. The laser emitter device 14 is secured to the base 16. The laser emitter device 14 is secured to the base 16 by means of a connection between the base 16 and the mounting plate 46. In this case, the connection is, for example, a soldered connection.

The soldered joint has a thermal conductivity of at least 35 watts/(meter*kelvin). Heat generated in the emitter 28 during the generation of the laser beam 34 is dissipated from the emitter 28 by means of the mounting plate 46 and the base 16.

The fast-axis collimator lens 30 is designed to collimate the laser beam 34 in the fast-axis direction 38. In other words, the laser beam 34 emitted by the laser emitter device 14 is collimated in the fast-axis direction 38.

The fast-axis collimator lens 30 is an aspherical cylindrical lens made of quartz glass, in this case made of quartz glass with a particularly high refractive index. The fast-axis collimator lens 30 has an anti-reflective coating which reduces the proportion of reflected light to a relative minimum for a wavelength of the laser beam 34. The anti-reflective coating reduces the reflectance of the laser beam 34 at the interfaces of the fast-axis collimator lens 30.

FIG. 5 shows that the fast-axis collimator lens 30 is secured to the mounting plate 46 by means of an adhesive bond. The adhesive bond is created by means of a UV adhesive. The UV adhesive is an adhesive that can be hardened by irradiation with ultraviolet light.

The fast-axis collimator lens 30 is positioned with respect to the emitter 28 in such a way that an emission direction 48, in which the laser emitter device 14 emits the laser beam 34, runs diagonally with respect to the longitudinal axis 32 of the emitter 28. In other words, by positioning the fast-axis collimator lens 30 with respect to the emitter 28, the laser emitter device 14 is designed to emit the laser beam 34 in the emission direction 48 which is diagonally aligned to the longitudinal axis 32 of the emitter 28. Due to the diagonal alignment of the emission direction 48, the emission direction 48 does not run parallel to the longitudinal axis 32 of the emitter 28.

The fast-axis collimator lens 30 can define a lens plane 50 and an optical plane 52. The lens plane 50 is the plane in which the fast-axis collimator lens 30 is arranged. A focal point of the fast-axis collimator lens 30 is spaced from the lens plane 50 by a focal length of the fast-axis collimator lens 30.

The optical plane 52 of the fast-axis collimator lens 30 is aligned to be perpendicular to the lens plane 50. The optical plane 52 of the fast-axis collimator lens 30 is a mirror symmetry plane of the fast-axis collimator lens 30. A laser beam passing through the fast-axis collimator lens 30 is refracted by the fast-axis collimator lens 30 in the direction of the optical plane 52.

The optical plane 52 intersects the lens plane 50 in a central axis 54 of the fast-axis collimator lens 30.

The fast-axis collimator lens 30 is positioned with respect to the emitter 28 in such a way that the longitudinal axis 32 of the emitter 28 and the optical plane 52 of the fast-axis collimator lens 30 have different orientations for the purpose of emitting the laser beam 34 in the emission direction 28. In other words, the fast-axis collimator lens 30 is arranged such that the longitudinal axis 32 of the emitter 28 is not within the optical plane 52.

The fast-axis collimator lens 30 is arranged with a transverse offset 56 in the fast-axis direction 38 with respect to the emitter 28. The transverse offset 56 is a distance between the longitudinal axis 32 of the emitter 28 and the central axis 54 of the fast-axis collimator lens 30. A distance between the longitudinal axis 32 of the emitter 28 and the flat surface section 26 is smaller than a distance between the central axis 54 of the fast-axis collimator lens 30 and the flat surface section 26.

Additionally, the fast-axis collimator lens 30 is tilted by a tilt angle 58 with respect to the longitudinal axis 32 of the emitter 28. The optical plane 52 of the fast-axis collimator lens 30 and the longitudinal axis 32 of the emitter 28 define the tilt angle 58 therebetween. The tilt angle 58 is 3° in the initial example shown.

Due to the transverse offset 56 and the tilt angle 58, the laser beam 34 generated by the emitter 28 is deflected away from the flat surface section 26 by the fast-axis collimator lens 30 in the fast-axis direction 38. By means of the transverse offset 56 and the tilt angle 58 of the fast-axis collimator lens 30, the laser emitter device 14 is designed to emit the laser beam 34 in the emission direction 48 which is diagonally aligned to the flat surface section 26.

The emission direction 48 and the flat surface section 26 define a radiation angle of 60 therebetween. The radiation angle 60 is 4° in the initial example shown.

The emission direction 48 is directed away from the flat surface section 26. The emission direction 48 can be decomposed into a directional component parallel to the planar surface section 26 and into a directional component perpendicular to the planar surface section 26. The directional component perpendicular to the flat surface section 26 is directed away from the flat surface section 26.

The laser beam 34 leaves the laser emitter device 14 by exiting the fast-axis collimator lens 30. The laser beam 34 exits the laser emitter device 14 at an exit region of the fast-axis collimator lens 30. The exit region of the fast-axis collimator lens 30 forms a laser emitter output 62 of the laser emitter device 14.

The direction of propagation 36 of the laser beam 34 after exiting the laser emitter device 14 is the same as the emission direction 48 in which the laser emitter device 14 emits the laser beam 34. In other words, after the laser beam exits the laser emitter device 14, the laser beam 34 propagates along the direction of propagation 36 thereof, which runs diagonally with respect to the flat surface section 26.

Due to the diagonal emission of the laser beam 34 in the emission direction 48 from the laser emitter device 14, a distance 64 between the laser beam 34 and the flat surface section 26 depends on a propagation path of the laser beam 34. A propagation path can be understood as the distance that the laser beam travels through propagation in the direction of propagation.

The distance 64 is determined in a direction parallel to a perpendicular on the flat surface section 26 from the flat surface section 26 to the laser beam 34. The distance 64 can also be understood as a height at which the laser beam 34 is spaced from the flat surface section 26. Since the laser beam 34 is emitted away from the flat surface section 26 by the laser emitter device 14, the distance 64 increases with increasing propagation path of the laser beam 34 from the laser emitter device 14.

FIG. 1 shows that the laser emitter devices 14 are arranged on the flat surface section 26 such that the slow-axis directions 40 of the laser beams 34 are aligned to be parallel to the flat surface section 26. The emission directions 48 are aligned to be parallel to each other. The directions of propagation 36 are aligned to be parallel to each other. The longitudinal axes 32 of the emitters 28 are aligned to be parallel to each other.

Each laser emitter output 62 of the laser emitter devices 14, from which the laser beam 34 emerges, is spaced at a distance from the flat surface section 26. The distances of the laser emitter outputs 62 of the laser emitter device 14 from the flat surface section 26 are equal in magnitude.

The laser emitter devices 14 are arranged on the flat surface section 26 such that the laser emitter outputs 62 are arranged along a straight line. The straight line of the laser emitter outputs 62 is aligned to be parallel to the flat surface section 26.

The laser emitter devices 14 are arranged on the flat surface section 26 in the form of a laser emitter array 66. A direction 68 of the laser emitter array 66 runs parallel to the flat surface section 26. Two adjacent laser emitter devices 14 are arranged at a distance 70 from each other on the flat surface section 26. The distances 70 between the laser emitter devices 14 are equal.

In the direction of propagation 36 according to the laser emitter devices 14, a plurality of slow-axis collimator lenses 72 of the laser emitter assembly 10 are arranged on the flat surface section 26. The slow-axis collimator lenses 72 are identically designed. In total, the laser emitter array 10 has 11 slow-axis collimator lenses 72. The number of slow-axis collimator lenses 11 corresponds to the number of laser emitter devices 14. Therefore, if fewer or more laser emitter devices 14 are present in exemplary embodiments not specifically shown, the number of slow-axis collimator lenses 11 is also changed accordingly.

Accordingly, each slow-axis collimator lens 72 is paired with a laser emitter device 14 of the laser emitter assembly 10. This means that the number of slow-axis collimator lenses 72 is equal to the number of laser emitter devices 14.

Each slow-axis collimator lens 72 is designed to collimate the laser beam 34 in the slow-axis direction 40. In other words, each laser beam 34 that passes through the slow-axis collimator lens 72 is collimated in the slow-axis direction 40.

Each slow-axis collimator lens 72 is an aspherical cylindrical lens made of quartz glass. The slow-axis collimator lens 72 has an anti-reflective coating for a wavelength of the laser beam 34, i.e., to reduce a proportion of reflected light of the laser beam 34 at the slow-axis collimator lens 72 to a relative minimum.

Each slow-axis collimator lens 72 is secured to the base 16 by means of an adhesive connection as shown here. The adhesive bond is created by means of a UV adhesive.

The slow-axis collimator lenses 72 are arranged on the flat surface section 26 to form a slow-axis collimator lens array 74. A direction 76 of the slow-axis collimator lens array 74 runs parallel to the flat surface section 26. The direction 76 of the slow-axis collimator lens array 74 runs parallel to the direction 68 of the laser emitter array 66.

In the direction of propagation 36 after the slow-axis collimator lenses 72, a plurality of deflecting mirrors 78 of the laser emitter assembly 10 are arranged on the flat surface section 26. The deflecting mirrors 78 are identical in design. In total, the laser emitter assembly 10 has 11 deflecting mirrors 78.

Each deflecting mirror 78 is paired with a laser emitter device 14 of the laser emitter assembly 10. This means that the number of deflecting mirrors 78 is equal to the number of laser emitter devices 14.

Each deflecting mirror 78 is secured to the base 16 by means of an adhesive connection. The adhesive bond is created by means of a UV adhesive.

Each deflecting mirror 78 is designed to deflect the direction of propagation 36 of the laser beam 34 of the laser emitter device 14 paired with the deflecting mirror 78 by 90°. In other words, each laser beam 34 strikes the deflecting mirror 78 at an angle of incidence of 45°. Deflecting the laser beam 34 by means of the deflecting mirror 78 is a change in the direction of propagation 36 of the laser beam 34.

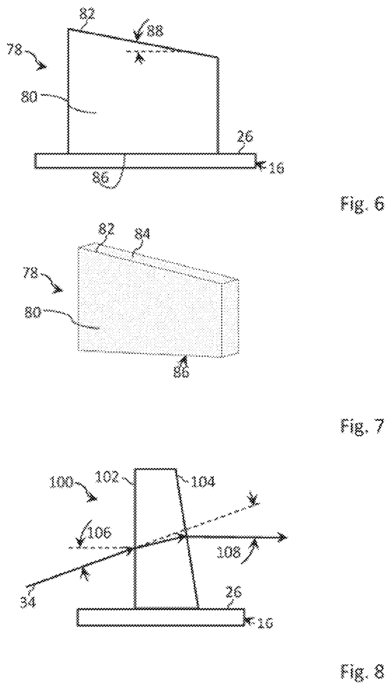

FIG. 6 shows a deflecting mirror 78 of the laser emitter assembly 10 and the base 16. FIG. 7 shows the deflecting mirror 78 of FIG. 6 without the base 16.

The deflecting mirror 78 has a mirror surface of 80. The mirror surface 80 is aligned to be perpendicular to the flat surface section 26.

The mirror surface 80 is designed to deflect the direction of propagation 36 of the laser beam 34 of the laser emitter device 14 paired with the deflecting mirror 78. In particular, the mirror surface 80 is designed to reflect the laser beam 34 of the laser emitter device 14 paired with the deflecting mirror 78.

The mirror surface 80 is formed from alternating, thin layers of different refractive indices. In other words, the deflecting mirror 78 is a Bragg mirror.

The deflecting mirror 78 has a straight edge 82 which runs diagonally with respect to the flat surface section 26. In other words, the straight edge 82 is aligned diagonally to the flat surface section 26. The diagonally-aligned straight edge 82 is formed without curvature and extends along a straight line.

The diagonally-aligned straight edge 82 forms a corner of the deflecting mirror 78. The diagonally-aligned straight edge 82 limits the mirror surface 80. The diagonally-aligned straight edge 82 bounds a side surface 84 of the deflecting mirror 78, which is turned away from the planar surface section 26. The side surface 84 is aligned to be perpendicular to the mirror surface 80. The diagonally-aligned straight edge 82 is a boundary between the mirror surface 80 and the side surface 84 facing away from the flat surface section 26. In other words, the diagonally-aligned straight edge 82 is arranged between the mirror surface 80 and the side surface 84 facing away from the flat surface section 26.

The deflecting mirror 78 has another side surface 86. The other side surface 86 is arranged to be opposite to the side surface 84. The other side surface 86 faces the flat surface section 26. The side surface 84 and the other side surface 86 are aligned in opposite directions to each other.

The diagonal run of the straight edge 82 and the flat surface section 26 define an angle 88 therebetween. The angle 88 between the diagonally-running straight edge 82 and the flat surface section 26 satisfies the condition

$${α}^{′} = a tan ( \frac{tan α}{\sqrt{2}} ) ,$$

wherein α is the radiation angle 60 and a′ is the angle 88.

FIG. 1 shows that the deflecting mirrors 78 are arranged on the flat surface section 26, forming an array of deflecting mirrors 90. A direction 92 of the deflecting mirror array 90 runs parallel to the flat surface section 26. The direction 92 of the deflecting mirror array 90 runs parallel to the direction 68 of the laser emitter array 66. The direction 92 of the deflecting mirror array 90 runs parallel to the direction 76 of the slow-axis collimator lens array 74.

Each deflecting mirror 78, except for the deflecting mirror 78 located closest to the output 12, deflects the respective laser beam 34 in such a way that the deflected laser beam 34 passes by the straight edge 82 with the diagonal run of another deflecting mirror 78. The further deflecting mirror 78 is arranged between the laser beam 34 deflected by the deflecting mirror 78 and the flat surface section 26.

The diagonal emission of the laser beams 34 enables the use of identically designed deflecting mirrors 78. The deflecting mirrors 78 are spaced apart from each other in the direction 92 of the deflecting mirror array 90 such that the distances 64 between the laser beams 34 and the flat surface section 26 increase for a propagation path equal to the distance between two adjacent deflecting mirrors 78 such that the laser beams 34 are guided past the deflecting mirrors 78 without grazing them.

Each deflecting mirror 78 is spaced at a distance 94 from the laser emitter device 14 paired with the deflecting mirror 78. The distances 94 between each deflecting mirror 78 and the laser emitter device 14 paired with the deflecting mirror 78 are equal.

Each deflecting mirror 78 is spaced apart from the output 12 by a distance 96. The distances 96 differ from each other. As a result, each laser beam 34 travels a different propagation path from the laser emitter device 14 to the output 12. As a result, the distances 64 between the laser beams 34 and the flat surface section 26 at output 12 differ from each other.

The directions of propagation 36 of the laser beams 34 are aligned to be parallel to each other after deflection by means of the deflecting mirrors 78. The laser beams 34 are arranged one above the other in the fast-axis direction 38 after being deflected by means of the deflecting mirrors 78. The deflecting mirrors 78 are designed to arrange the laser beams 34 one above the other in such a way that the laser beams 34 are spaced apart at an equal distance from each other.

The output laser beam 98 is formed by arranging the individual laser beams 34 with respect to each other by means of the deflecting mirrors 78. The output laser beam 98 is a laser beam group formed from the laser beams 34. The forming of the output laser beam 98 is an arrangement of the laser beams 34 in the fast-axis direction 38 one above the other by means of the deflecting mirrors 78.

The output laser beam 98 propagates in a direction of propagation. In other words, the formed laser beam group propagates in a direction of propagation which results from the individual directions of propagation 36 of the laser beams 34. Since the directions of propagation 36 of the laser beams 34 are aligned to be parallel to each other after deflection by means of the deflecting mirrors, the direction of propagation of the output laser beam 98 is aligned to be parallel to all directions of propagation 36 of the laser beams 34.

In the direction of propagation 36 after the deflecting mirrors 78, an optical device 100 of the laser emitter assembly 10 is arranged on the flat surface section 26. The optical device 100 is arranged in a beam path of the laser beams 34 between the output 12 and the deflecting mirrors 78.

The optical device 100 is designed as a one-piece optical component of the laser emitter assembly 10. The optical device 100 is designed as an independent optical component of the laser emitter assembly 10. In other words, the optical device 100 is designed separately from the other optical components of the laser emitter assembly 10.

The optical device 100 is secured to the base 16 by means of an adhesive connection. The adhesive bond is created by means of a UV adhesive.

The laser beams 34 pass through the optical device 100 for the purpose of changing the directions of propagation 36. The optical device 100 is transparent to a wavelength of the laser beams 34.

FIG. 8 shows the optical device 100 of the laser emitter assembly 10 and the base 16. The optical device 100 is designed as an optical wedge made of quartz glass.

The optical device 100 has a flat entry surface 102 and a flat exit surface 104. The flat entry surface 102 and the flat exit surface 104 run diagonally to each other.

The laser beams 34 strike the flat entry surface 102 of the optical device 100, pass through the optical device 100 and exit from the flat exit surface 104 of the optical device 100.

Each laser beam 34 strikes the flat entry surface 102 at an angle of incidence 106. The angle of incidence 106 is defined by a perpendicular on the flat entry surface 102 and the direction of propagation 36 of the laser beam 34. All angles of incidence 106 are the same.

The flat entry surface 102 and the flat exit surface 104 each form a phase boundary for the laser beams 34. The optical device 100 is designed to change each direction of propagation 36 of the laser beams 34 in the fast-axis direction by refraction at the flat entry surface 102 and at the flat exit surface 104. In other words, the optical device 100 is designed to change the directions of propagation 36 of the laser beams 34 in the direction of the planar surface section 26 by refraction at the planar entry surface 102 and at the planar exit surface 104. This deflects the laser beams 34 by means of the optical device 100 in the direction of the flat surface section 26.

The optical device 100 is designed to change each direction of propagation 36 of the laser beams 34 by a deflection angle 108. Each deflection angle 108 is defined between the direction of propagation 36 of the laser beam 34 before passing through the optical device 100 and the direction of propagation 36 of the laser beam 34 after passing through the optical device 100. Each deflection angle 108 of the laser beams 34 and the radiation angle 60 of the laser beams 34 is the same.

After passing through the optical device 100, the direction of propagation of the output laser beam 98 is aligned to be parallel to the flat surface section 26. Each laser beam 34 propagates parallel to the flat surface section 26 after passing through the optical device 100. In other words, after passing through the optical device 100, the directions of propagation 36 of the laser beams 34 are aligned to be parallel to the flat surface section 26. This allows the optical device 100 to compensate for the diagonally-running emission directions 48.

In the direction of propagation 36 after the optical device 100, each distance 64 between the laser beam 34 and the flat surface section 26 is constant. In other words, once a laser beam 34 has passed through the optical device 100, the distance 64 between the laser beam 34 and the flat surface section 26 no longer changes depending on the propagation path of the laser beam 34.

In the direction of propagation 36 after the optical device 100, a focusing device 110 of the laser emitter assembly 10 is arranged on the flat surface section 26. The focusing device 110 is secured to the base 16 by means of an adhesive connection. The adhesive bond is created by means of a UV adhesive.

The focusing device 110 is designed to focus the output laser beam 98 onto the output 12. The focusing device 110 is designed as a focusing lens made of quartz glass. The focusing device 110 has an anti-reflective coating for a wavelength of the laser beams 34 of the laser emitter devices 14. The anti-reflective coating reduces the reflectance of the laser beam 34 at the interfaces of the focusing device 110.

The focusing device 110 is arranged on the flat surface section 26 such that the output 12 lies in a focal plane of the focusing device 110 in the direction of propagation of the output laser beam 98 after the focusing device 110.

The focusing device 110 focuses the output laser beam 98 onto the output 12 such that the output laser beam 98 has a predetermined beam diameter and a predetermined divergence at the output 12. In other words, the output laser beam 98 exits the output with the specified beam diameter and divergence. In the initial example shown, the specified beam diameter is 400 μm and the specified divergence is 40°.

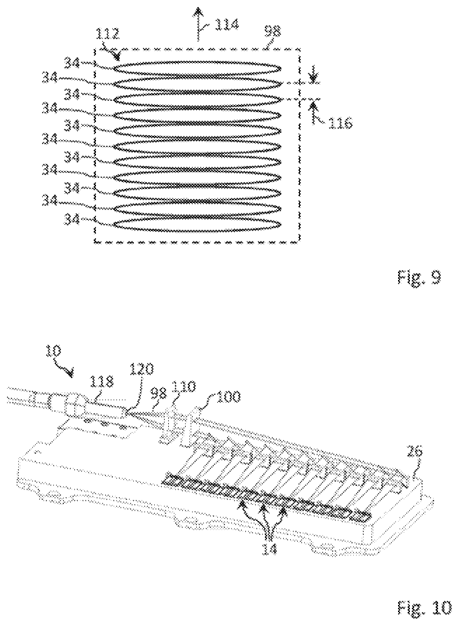

FIG. 9 schematically shows a cross-section of the output laser beam 98 at the output 12. A beam profile of the output laser beam 98 is formed by the laser beams 34 arranged one above the other in the fast-axis direction 38. The laser beams 34 are arranged with respect to each other in the cross-section, forming a laser beam array 112. A direction 114 of the laser beam array 112 is aligned to be perpendicular to the flat surface section 26.

The laser beams 34 are arranged one above the other at an equal distance 116 in the fast-axis direction 38. Each distance 116 between two adjacent laser beams 43 depends on the propagation paths of the two adjacent laser beams 43 from the laser emitter devices 14 emitting the two adjacent laser beams 43 to the optical device 100.

For example, the distance 116 between the two adjacent laser beams 43 changes when the propagation path of one of the two adjacent laser beams 43 between the laser emitter device 14 emitting the laser beam 43 and the optical device 100 is lengthened or shortened. The dependence of the output laser beam 98 on the propagation paths is achieved by the diagonal run of the directions of propagation 36 of the laser beams 34 in relation to the flat surface section 26.

Thus, the positions of the laser beams 34 in the cross-section of the output laser beam 98 are determined by the propagation paths from the laser emitter devices 14 to the output 12. In other words, the output laser beam 98 is formed depending on the propagation paths from the laser emitter devices 14 to the output 12. The dependence on the propagation paths is a dependence on the lengths of the propagation paths.

The lengths of the propagation paths of the laser beams 34 depend on an arrangement of the laser emitter devices 14 on the flat surface section 26. This means that the output laser beam 98 is formed from the laser beams 34 depending on the positions of the laser emitter devices 14 on the flat surface section 26.

In the illustrated exemplary embodiment, the laser emitter assembly 10 has a housing, not shown. The base 16 forms a side wall of the housing. The housing has an interior in which are arranged the laser emitter devices 14, the slow-axis collimator lenses 72, the deflecting mirrors 78, the optical device 100, and the focusing device 110. Output 12 is formed by an opening in the housing. The output laser beam 98 is focused on the aperture by means of the focusing device 110. The output laser beam 98 passes through the opening and exits the housing.

FIG. 10 shows a further exemplary embodiment of a laser emitter assembly 10, wherein the same reference symbols are used for identical and functionally equivalent elements and, in this respect, reference can be made to the explanations given above in relation to the exemplary embodiment of FIGS. 1 to 9, with the result that essentially only the existing differences are discussed.

The laser emitter assembly 10 of the FIG. 10 has a waveguide receptacle, not shown, for receiving a waveguide 118 in the form of an optical fiber cable for guiding the output laser beam 98. The receptacle is located at an opening in the housing of the laser emitter assembly 10. The waveguide 118 is included in the receptacle. The waveguide 118 is taken up by the receptacle in such a way that an end face 120 of the waveguide 118 is arranged at the output 12. The output laser beam 98 is focused onto the output 12 by means of the focusing device 110 in such a way that the output laser beam 98 is coupled into the waveguide 118. The output laser beam 98 is thus designed to be coupled into the waveguide 118 if the end face 120 of the waveguide 118 is arranged, in particular placed, at the output 12.

FIG. 11 shows a further exemplary embodiment of a laser emitter arrangement 10, wherein the same reference symbols are used for identical and functionally equivalent elements, and reference can therefore be made to the explanations given above in relation to the exemplary embodiments of FIGS. 1 to 10, so that essentially only the existing differences are addressed.

The laser emitter devices 14 are arranged on the flat surface section 26 of the base 16, forming a first laser emitter array 122 and a second laser emitter array 124. Each laser emitter array 122, 124 is formed from 9 laser emitter devices 14.

The first laser emitter array 122 extends in a direction 126. The direction 126 of the first laser emitter array 122 runs parallel to the flat surface section 26. The second laser emitter array 124 extends in a direction 128. The direction 128 of the second laser emitter array 124 runs parallel to the flat surface section 26. The direction 126 of the first laser emitter array 122 is aligned to be parallel to the direction 128 of the second laser emitter array 124.

The first laser emitter array 122 and the second laser emitter array 124 are aligned to be offset from each other. The first laser emitter array 122 and the second laser emitter array 124 are aligned to be offset from each other in such a way that between two adjacent laser emitter devices of the second laser emitter array 124 a laser beam 34 of a laser emitter device 14 of the first laser emitter array 122 is guided past the two adjacent laser emitter devices 14 of the second laser emitter array 124. This means that the laser beams 34 in the cross-section of the output laser beam 98 at the output 12 are arranged with respect to each other in such a way that between two adjacent laser beams 34 of the laser emitter device 14 of the first laser emitter array 122 a laser beam 34 of the laser emitter device 14 of the second laser emitter array 124 is arranged.

The slow-axis collimator lenses 72 are arranged on the flat surface section 26 to form a first slow-axis collimator lens array 130 and a second slow-axis collimator lens array 132. The slow-axis collimator lenses 72 of the first slow-axis collimator lens array 130 are paired with the laser emitter devices 14 of the first laser emitter array 122. The slow-axis collimator lenses 72 of the second slow-axis collimator lens array 132 are paired with the laser emitter devices 14 of the second laser emitter array 124.

Each laser emitter device 14 of the first laser emitter array 122 is spaced apart by a distance 134 from the deflecting mirror 78 paired with the laser emitter device 14. Each laser emitter device 14 of the second laser emitter array 124 is spaced apart by a distance 136 from the deflecting mirror 78 paired with the laser emitter device 14.

The distance 134 between the laser emitter devices 14 of the first laser emitter array 122 and the deflecting mirrors 78 is greater than the distance 136 between the laser emitter devices 14 of the second laser emitter array 124 and the deflecting mirrors 78.

The radiation angles 60 between the emission directions 48 of the laser emitter devices 14 of the first laser emitter array 122 and the flat surface section 26 are smaller in the magnitudes thereof than the magnitudes of the radiation angles 60 between the emission directions 48 of the laser emitter devices 14 of the second laser emitter array 124 and the flat surface section 26.

The deflecting mirrors 78, which are paired with the laser emitter devices 14 of the second laser emitter array 122, are each aligned to be orthogonal to the planar surface section 26.

The deflecting mirrors 78, which are paired with the laser emitter devices 14 of the first laser emitter array 122, are each aligned with a tilt angle to the flat surface section 26. In the illustrated exemplary embodiment, the deflecting mirrors 78, which are paired with the laser emitter devices 14 of the first laser emitter array 122, are each aligned with the tilt angle to the flat surface section 26 such that the laser beams 34 of the laser emitter devices 14 of the first laser emitter array 122 and the laser beams 34 of the laser emitter devices 14 of the second laser emitter array 124 are aligned to be parallel to each other after deflection by means of the deflecting mirrors 78.

In the initial example of FIG. 11, the focusing device 110 has a first cylindrical lens 138 and a second cylindrical lens 140. The first cylindrical lens 138 and the second cylindrical lens 140 are designed to focus the output laser beam 98 onto the output 12.

The first cylindrical lens 138 and the second cylindrical lens 140 are each an aspherical cylindrical lens made of quartz glass with a comparatively high refractive index. The first cylindrical lens 138 and the second cylindrical lens 140 each have an anti-reflective coating for a wavelength of the laser beams 34. In exemplary embodiments not specifically shown, the cylindrical lenses 140 are spherically shaped.

The first cylindrical lens 138 is designed to focus the output laser beam 98 in the fast-axis direction 38 onto the output 12. The second cylindrical lens 140 is designed to focus the output laser beam 98 in the slow-axis direction 40 onto the output 12.

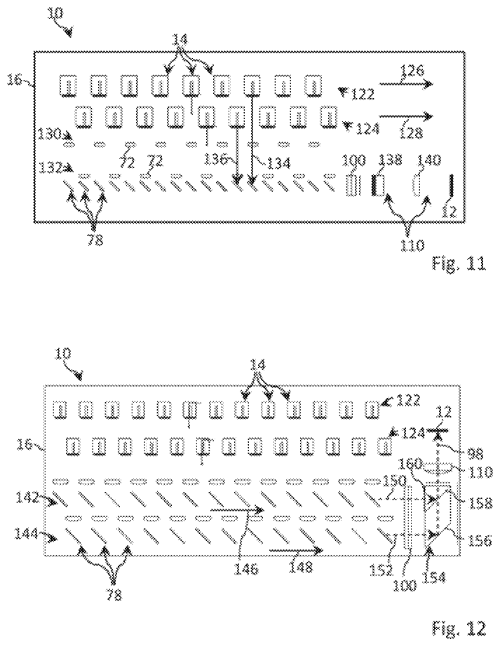

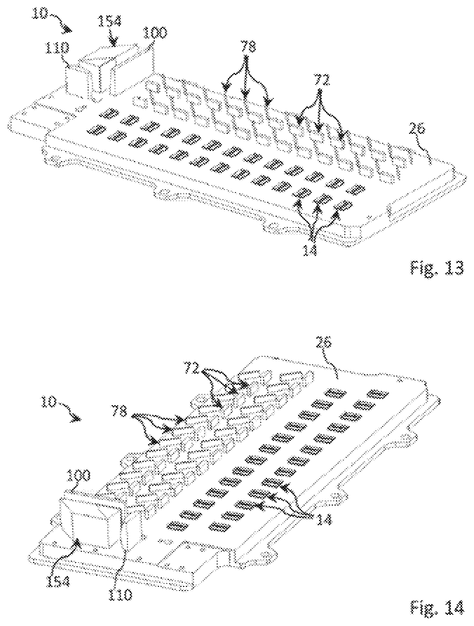

FIGS. 12 to 14 show a further exemplary embodiment of a laser emitter arrangement 10, wherein identical and functionally equivalent elements are given the same reference symbols, and reference can therefore be made to the foregoing explanations of the embodiments of FIGS. 1 to 11, so that essentially only the existing differences are addressed.

Each laser emitter array 122, 124 is formed from 13 laser emitter devices 14.

The deflecting mirrors 78 are arranged on the flat surface section 26, forming a first deflecting mirror array 142 and a second deflecting mirror array 144.

The first array of deflecting mirrors 142 extends in a direction 146. The direction 146 of the first deflecting mirror array 142 runs parallel to the flat surface section 26. The second array of deflecting mirrors 144 extends in a direction 148. The direction 148 of the second deflecting mirror array 144 runs parallel to the flat surface section 26. The direction 146 of the first deflecting mirror array 142 is aligned to be parallel to the direction 148 of the second deflecting mirror array 144.

The first deflecting mirror array 142 is paired with the laser emitter device 14 of the first laser emitter array 122. The second deflecting mirror array 144 is paired with the laser emitter devices 14 of the second laser emitter array 124.

The first array of deflecting mirrors 142 and the second array of deflecting mirrors 144 are arranged to be offset from each other on the flat surface section 26. The first deflecting mirror array 142 and the second deflecting mirror array 144 are arranged to be offset from each other in such a way that a laser beam 34 of a laser emitter device 14 of the second laser emitter array 124 is guided between two adjacent deflecting mirrors 78 of the first deflecting mirror array 142.

By means of the first deflecting mirror array 142, the laser beams 34 of the laser emitter devices 14 of the first laser emitter array 122 are arranged one above the other in the fast-axis direction 38. The laser beams 34 of the laser emitter devices 14 of the first laser emitter array 122 arranged one above the other in the fast-axis direction 38 form a first laser beam group 150. The first laser beam group 150 is represented in FIG. 12 by a dashed arrow.

By means of the second deflecting mirror array 144, the laser beams 34 of the laser emitter devices 14 of the second laser emitter array 124 are arranged one above the other in the fast-axis direction 38. The laser beams 34 of the laser emitter devices 14 of the second laser emitter array 124 arranged one above the other in the fast-axis direction 38 form a second laser beam group 152. The second laser beam group 152 is represented in FIG. 12 by a dashed arrow.

The two laser beam groups 150, 152 propagate parallel and offset from each other. The two laser beam groups 150, 152 pass through the optical device 100 at different points.

The laser emitter assembly 10 has a polarization coupling device 154. The output laser beam 98 is formed by polarization coupling of the two laser beam groups 150, 152 to one another. The output laser beam 98 is represented in FIG. 12 by a dashed arrow.

The polarization coupling device 154 has a mirror 156, a polarizer 158, and a delay plate in the form of a λ/2 plate 160. The polarization coupling device 154 is designed as a single, in particular only, component.

The laser beams 34 are linearly polarized. The linear polarizations of the laser beams 34 are aligned to be parallel to each other before passing through the polarization coupling device 154. In other words, before passing through the polarization coupling device 154, the polarization of all laser beams 34 is aligned in the same way.

The λ/2 plate 160 is arranged such that the laser beams 34 of the first laser beam group 150 pass through the λ/2 plate. The λ/2 plate 160 is designed to rotate the polarization of the laser beams 34 of the first laser beam group 150 by 90°. This means that the polarization of the laser beams 34 of the first laser beam group 150 is aligned to be orthogonal to the polarization of the second laser beam group 152.

After passing through the λ/2 plate, the laser beams 34 of the first laser beam group 150 strike the polarizer 158. The polarizer 158 is designed to reflect or to transmit the laser beams 34 depending on the polarization thereof. In the illustrated exemplary embodiment of the FIG. 12 the polarizer 158 reflects the laser beams 34 of the first laser beam group 150 due to the alignment of the polarization thereof.

The second laser beam group 152 strikes the mirror 156 as it passes through the polarization coupling device 154. The second laser beam group 152 is deflected by 90° by the mirror 156. By deflecting the second laser beam group 152 by means of the mirror 156, the second laser beam group 152 is directed towards the polarizer 158. In the illustrated initial example shown in FIG. 12, the polarizer 158 transmitted the laser beams 34 of the second laser beam group 152 due to the alignment of the polarization thereof.

The polarizer 158 spatially superimposes the laser beams 34 of the first laser beam group 150 with the laser beams 34 of the second laser beam group 152 to form the output laser beam 98. In other words, the output laser beam 98 is formed by means of the polarizer 158 by spatially superimposing the laser beams 34 of the first laser beam group 150 with the laser beams 34 of the second laser beam group 152.

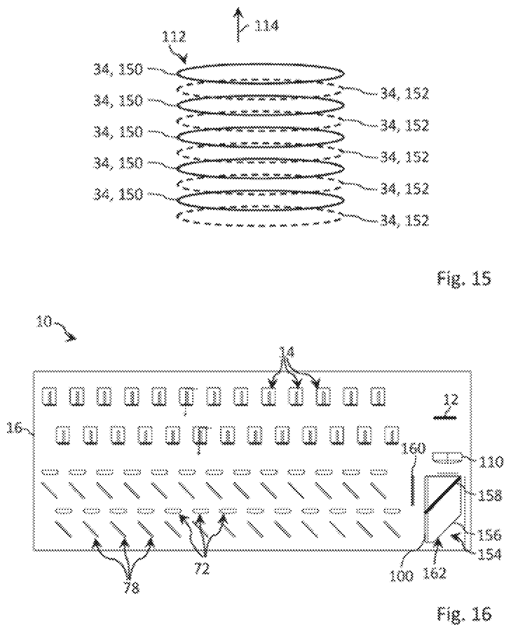

FIG. 15 schematically shows a section of a cross-section of the output laser beam 98 at the output 12, wherein for the sake of clarity not all laser beams 34 of the laser emitter devices 14 are shown in FIG. 15. The laser beams 34 of the second laser beam group 152 are shown in FIG. 15 as dashed lines.

The output laser beam 98 is formed by polarization coupling by means of the polarization coupling device 154 such that a laser beam 34 of the second laser beam group 152 is arranged at the output between two adjacent laser beams 34 of the first laser beam group 150. The laser beams 34 of the first laser beam group 150 and the laser beams 34 of the second laser beam group 152 overlap in some regions. However, it is also conceivable to implement an exemplary embodiment in which the laser beams 34 do not overlap.

In an alternative exemplary embodiment, not shown, the output laser beam is formed by spatially superimposing the laser beams of the first laser beam group with the laser beams of the second laser beam group by wavelength coupling by means of a wavelength coupling device of the laser emitter assembly.

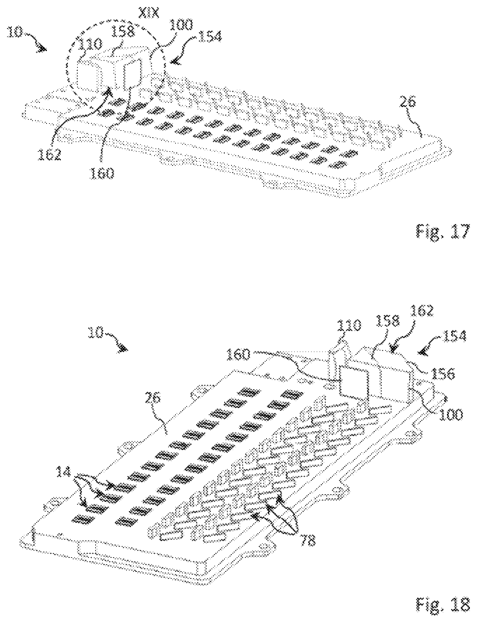

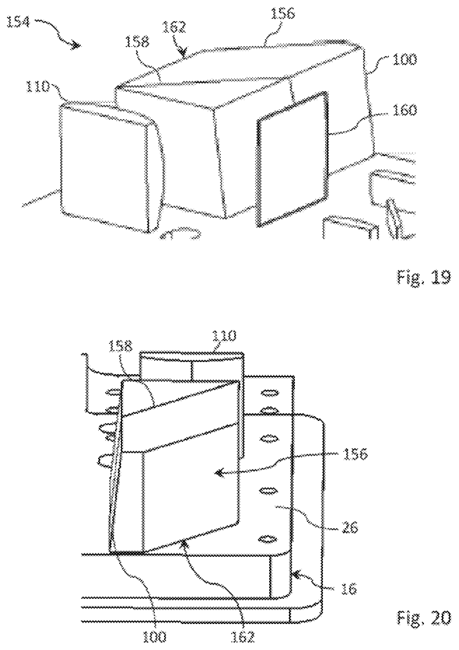

FIGS. 16 to 21 show a further exemplary embodiment of a laser emitter arrangement 10 is shown, wherein identical and functionally equivalent elements are denoted by the same reference symbols, and reference can therefore be made to the above explanations regarding the embodiments of FIGS. 1 to 15, so that essentially only the existing differences are discussed.

The optical device 100 is connected in a material-fitting manner to the polarizer 158 of the polarization coupling device 154 and the mirror 156 of the polarization coupling device 154, forming a coupling element 162 of the laser emitter assembly 10. In other words, the coupling element 162 is designed as a single component. The coupling element 162 is made of quartz glass.

The λ/2 plate 160 of the polarization coupling device 154 is designed separately from the coupling element 162.

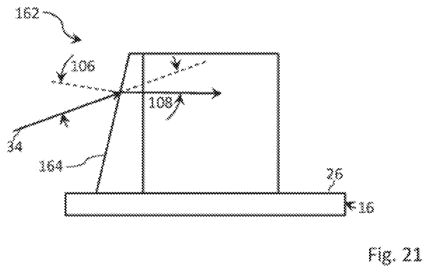

FIG. 21 shows the coupling element 162 of the laser emitter assembly 10 and the base 16.

The optical device 100 is formed by a flat entry surface 164 of the coupling element 162. The flat entrance surface 164 is aligned at an angle to the flat surface section 26. Each laser beam 34 strikes the flat entry surface 164 at an angle of incidence 106.

The flat entry surface 164 forms a phase boundary for the laser beams 34. Each direction of propagation 36 of the laser beams 34 is changed by refraction at the flat entry surface 164 onto the flat surface section 26. This changes the directions of propagation 36 of the laser beams 34 by the deflection angle 108.

After passing the flat entry surface 164, the directions of propagation 36 of the laser beams 34 are aligned to be parallel to the flat surface section 26.

A method according to embodiments of the invention is configured to operate a previously described laser emitter assembly.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

1. A laser emitter assembly for providing an output laser beam at an output of the laser emitter assembly, the laser emitter assembly comprising:
a base,
a plurality of laser emitter devices, and
a plurality of deflecting mirrors secured to the base,
each respective laser emitter device being configured to generate a respective laser beam, each respective deflecting mirror being paired with a respective laser emitter device,
each respective deflecting mirror being configured to deflect the respective laser beam of the respective laser emitter device paired with the respective deflecting mirror,
each respective deflecting mirror having a straight edge that runs diagonally with respect to the base, and
the output laser beam being formed from the laser beams of the plurality of laser emitter devices.

2. The laser emitter assembly according to claim 1,
wherein in each respective deflecting mirror, the straight edge limits a side surface of the respective deflecting mirror that faces away from the base.

3. The laser emitter assembly according to claim 1,
wherein the base has a flat surface section,
wherein the plurality of deflecting mirrors is arranged on the flat surface section, and
wherein in each respective deflecting mirror, the straight edge runs diagonally with respect to the flat surface section.

4. The laser emitter assembly according to claim 1,
wherein each respective laser beam propagates along a direction of propagation, and
wherein each respective deflecting mirror is configured to deflect the direction of propagation of the respective laser beam of the respective laser emitter device paired with the respective deflecting mirror by 80° to 100°.

5. The laser emitter assembly according to claim 1,
wherein the plurality of laser emitter devices is secured to the base,
wherein each respective laser emitter device is configured to emit the respective laser beam in an emission direction,
wherein the emission direction and the base define a radiation angle α therebetween, and
wherein in each respective deflecting mirror, the straight edge and the base define an angle α′ therebetween, wherein the angle α′ is dependent on the radiation angle α.

6. The laser emitter assembly according to claim 5,
wherein the angle α′ is defined by
$${α}^{′} = a tan ( \frac{tan α}{\sqrt{2}} ) .$$

7. The laser emitter assembly according to claim 1,
wherein at least one deflecting mirror of the plurality of deflecting mirrors is configured so as to deflect the respective laser beam of the respective laser emitter device paired with the at least one deflecting mirror in such a way that a deflected laser beam is guided past the straight edge of another deflecting mirror of the plurality of deflecting mirrors.

8. The laser emitter assembly according to claim 1,
wherein the plurality of deflecting mirrors is secured to the base forming at least one array of deflecting mirrors.

9. The laser emitter assembly according to claim 8,
wherein the plurality of laser emitter devices is secured to the base forming at least one laser emitter array.

10. The laser emitter assembly according to claim 9,
wherein the deflecting mirror array and the laser emitter array are arranged to be parallel to each other.

11. The laser emitter assembly according to claim 1,
wherein the plurality of deflecting mirrors is secured to the base forming a first deflecting mirror array and a second deflecting mirror array.

12. The laser emitter assembly according to claim 11,
wherein the first deflecting mirror array and the second deflecting mirror array are aligned to be parallel to each other.

13. The laser emitter assembly according to claim 11,
wherein the first deflecting mirror array and the second deflecting mirror array are arranged to be offset from each other.

14. The laser emitter assembly according to claim 11,
wherein the output laser beam is formed by polarization coupling and/or wavelength coupling of the laser beams deflected by the first deflecting mirror array with the laser beams deflected by the second deflecting mirror array.

15. The laser emitter assembly according to claim 1,
wherein each respective laser beam travels a propagation path from the respective laser emitter device generating the respective laser beam to the output of the laser emitter assembly, and
wherein the output laser beam is formed from the laser beams of the plurality of laser emitter devices depending on the propagation paths from the plurality of laser emitter devices to the output.
